(19) United States
(12) Patent Application Publication
(10) Pub. No.: US 2026/0262181 A1
(43) Pub. Date: Sep. 3, 2026

(54) ELECTRONIC DEVICE COMPRISING FLEXIBLE DISPLAY

(71) Applicant: Samsung Electronics Co., Ltd., Suwon-si (KR)

(72) Inventors: Soonwan CHUNG, Suwon-si (KR); Jeayou KIM, Suwon-si (KR); Kwonho SONG, Suwon-si (KR); Myunggwan PARK, Suwon-si (KR)

(21) Appl. No.: 19/654,241

(22) Filed: Apr. 21, 2026

Related U.S. Application Data
(63) Continuation of application No. PCT/KR2024/017130, filed on Nov. 4, 2024.

(30) Foreign Application Priority Data
Nov. 17, 2023 (KR) 10-2023-0159872
Dec. 8, 2023 (KR) 10-2023-0178014

(51) Int. Cl. H05K 5/02

(52) U.S. Cl. CPC H05K 5/0226

(57) ABSTRACT

An electronic device may include: a first housing; a second housing; a hinge assembly for rotatably coupling the first housing and the second housing; a flexible display; and a protective member comprising a polymer disposed on at least a portion of the periphery of the flexible display. The protective member may include a first protective member including a polymer disposed between the edge of the flexible display and a side wall of the housing, and a second protective member including an adhesive at least partially disposed between the rear surface of the flexible display and an inner wall of the housing.

### CROSS-REFERENCE TO RELATED APPLICATIONS

This application is a continuation of International Application No. PCT/KR2024/017130 designating the United States, filed on November 4, 2024, in the Korean Ministry of Intellectual Property Receiving Office and claiming priority to Korean Patent Application Nos. 10-2023-0159872, filed on November 17, 2023, and 10-2023-0178014, filed on December 8, 2023, in the Korean Ministry of Intellectual Property, the disclosures of each of which are incorporated by reference herein in their entireties.

### BACKGROUND

### FIELD

[1] The disclosure relates to a flexible display and an electronic device including the same.

### DESCRIPTION OF RELATED ART

[2] An electronic device requires a small profile for portability and requires a large-area display for providing users with substantial information. In order to achieve both a small profile and a large-area display in an electronic device, various form factors such as foldable, slidable, or rollable are emerging, departing from a rectangular bar-shaped form factor. An electronic device having such a form factor requires a flexible display capable of shape deformation by folding or bending.

[3] The flexible display may be disposed in a space formed by a housing. In a state in which the flexible display is mounted, a clearance (or a space) spaced apart by a predetermined distance may be present between a side surface of the flexible display and the housing, and this may be referred to as a "gap."

[4] During a bending operation of the flexible display, if a panel side protective member (e.g., a decorative member) implemented as a separate structure covering the gap is not used, the gap may not be completely sealed, and external foreign objects such as sand and dust may intrude into the panel side, causing panel damage due to foreign objects. Further, in case that the panel side protective member includes a joint portion having complex movability, the panel side protective member is assembled to a side surface of the flexible display through a separate assembly process, which may increase the complexity of a manufacturing process of the electronic device.

[5] Therefore, by filling the gap between the side surface of the flexible display and the housing with a protective member (e.g., a sealing member or a protective member), foreign objects may be prevented/blocked from intruding into the flexible display.

### SUMMARY

[6] Embodiments of the disclosure may provide an electronic device including a protective member configured to prevent and/or block foreign objects from being introduced into a side surface of a flexible display.

[7] An electronic device according to an example embodiment of the disclosure may include: a first housing, a second housing, a hinge assembly including a hinge disposed between the first housing and the second housing and rotatably coupling the first housing and the second housing, a flexible display including a first region corresponding to the first housing, a second region corresponding to the second housing, and a folding region corresponding to the hinge assembly and connecting the first region and the second region, and a protective member disposed on at least a portion of a periphery of the flexible display. The protective member may include a first protective member comprising a polymer material and disposed between an edge of the flexible display and a side wall of the first housing, and/or disposed between an edge of the flexible display and a side wall of the second housing, and a second protective member comprising an adhesive at least partially disposed between a rear surface of the flexible display and an inner wall of the first housing, and/or at least partially disposed between a rear surface of the flexible display and an inner wall of the second housing.

[8] An electronic device according to an example embodiment of the disclosure may include: a first housing, a second housing, a hinge assembly including a hinge disposed between the first housing and the second housing and rotatably coupling the first housing and the second housing, a flexible display including a first region corresponding to the first housing, a second region corresponding to the second housing, and a folding region corresponding to the hinge assembly and connecting the first region and the second region, and a protective member disposed on at least a portion of a periphery of the flexible display. The protective member may include a first protective member comprising a polymer material having a specified transparency, a specified permittivity and a specified dielectric loss disposed between an edge of the flexible display and a side wall of the first housing, and/or disposed between an edge of the flexible display and a side wall of the second housing.

[9] In an electronic device according to an example embodiment of the disclosure, a protective member preventing/blocking foreign objects from being introduced into a side surface of the flexible display may be provided.

An electronic device according to an example embodiment of the disclosure may provide a flexible display having a maximized active area and/or increased active area by minimizing and/or reducing a bezel of the flexible display.

A protective member according to an example embodiment of the disclosure comprises a material having a specified permittivity and a specified dielectric loss, and may provide antenna performance of a side housing.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a diagram illustrating an example electronic device in a network environment according to various example embodiments.

FIG. 2A is a front perspective view illustrating an example electronic device in an unfolded state according to various example embodiments.

FIG. 2B is a diagram illustrating a front view of an example electronic device in an unfolded state according to various example embodiments.

FIG. 2C is a diagram illustrating a rear view of an example electronic device in an unfolded state according to various example embodiments.

FIG. 2D is a perspective view illustrating an example electronic device in an intermediate state viewed from a front direction according to various example embodiments.

FIG. 2E is an exploded perspective view illustrating an example electronic device according to various example embodiments.

FIG. 3A is an exploded perspective view illustrating a flexible display according to various example embodiments.

FIG. 3B is a diagram illustrating a rear view of a flexible display viewed from a rear surface direction according to various example embodiments.

FIG. 4 is an enlarged partial cross-sectional view illustrating a portion of a flexible display and a housing according to various example embodiments.

FIG. 5 is an enlarged partial cross-sectional view illustrating a portion of a first protective member and a housing according to various example embodiments.

FIG. 6 is a flowchart illustrating example operations for filling a first protective member in a gap formed between a flexible display and a housing according to various example embodiments.

FIG. 7 is a perspective view illustrating a seating pad according to various example embodiments.

FIG. 8 is a partial cross-sectional view illustrating a display assembly fixed to a jig device according to various example embodiments.

FIG. 9 is a partial cross-sectional view illustrating a display assembly fixed to a jig device according to various example embodiments.

FIG. 10 is a diagram illustrating a shape of a first surface of a first protective member according to various example embodiments.

In connection to the description of the drawings, identical or similar reference numerals may be used for identical or similar components.

### DETAILED DESCRIPTION

Hereinafter, various example embodiments of the disclosure are described in greater detail with reference to the drawings. However, the disclosure may be implemented in various forms and is not limited to the example embodiments set forth herein. The same or similar reference denotations may be used to refer to the same or similar elements throughout the disclosure and the drawings. Further, for clarity and brevity, no description may be made of well-known functions and configurations in the drawings and relevant descriptions.

An electronic device to be described may include a flexible display that is at least one of a foldable display, a rollable display, a slidable display, or a stretchable display. The flexible display may deform due to folding or bending. The operation in which the flexible display is folded or bent may be referred to as "deformation of the display," and this may refer, for example, to deformation at a specific point according to characteristics of the flexible display. A region where the display is deformed may be referred to as a "variable region." Hereinafter, for convenience of description, an electronic device including a foldable display is mainly described, but the same may be applied to an electronic device including a flexible display deformed in various manners.

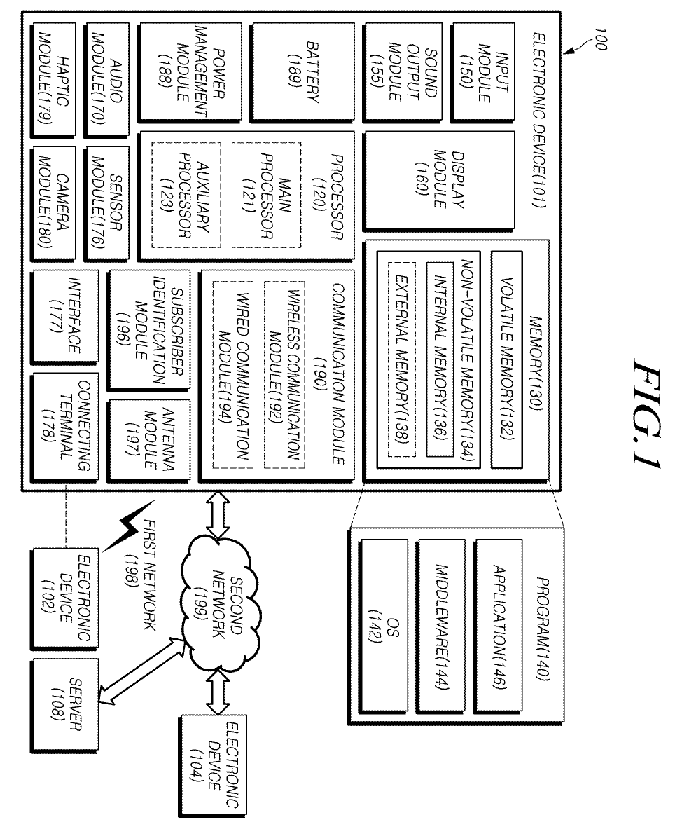

FIG. 1 is a block diagram illustrating an example electronic device in a network environment according to various example embodiments.

Referring to FIG. 1, an electronic device 101 in a network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, in case that the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited /disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the strength of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) (e.g., a speaker or a headphone) directly or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth^{TM}, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or U-plane latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form an mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

According to various embodiments, a portable electronic device (e.g., the electronic device 101 of FIG. 1) may have a foldable housing divided into two housings based on a folding axis. A first portion of a display (e.g., a flexible display) may be disposed in a first housing, and a second portion of the display may be disposed in a second housing. The foldable housing may be implemented in an in-folding manner where the first portion and the second portion face each other in case that the portable electronic device is folded. The foldable housing may be implemented in an out-folding manner where the first portion and the second portion face opposite directions in case that the portable electronic device is folded. A surface on which the first portion and the second portion of the display are disposed may be defined as a front surface of the portable electronic device, an opposite surface may be defined as a rear surface of the portable electronic device, and a surface surrounding a space between the front surface and the rear surface may be defined as a side surface of the portable electronic device.

According to an embodiment, in case that a display of the portable electronic device is folded, an in-folding case where the first portion of the display in the first housing is disposed to face the second portion of the display in the second housing is illustrated and described as an example, but according to an embodiment, in case that the display is folded, the same may be applied to an out-folding case where the first portion of the display in the first housing 210 is disposed to face a direction opposite to the second portion of the display in the second housing. Various embodiments may be applied to a multi-foldable electronic device in which in-folding and in-folding are combined, in-folding and out-folding are combined, or out-folding and out-folding are combined.

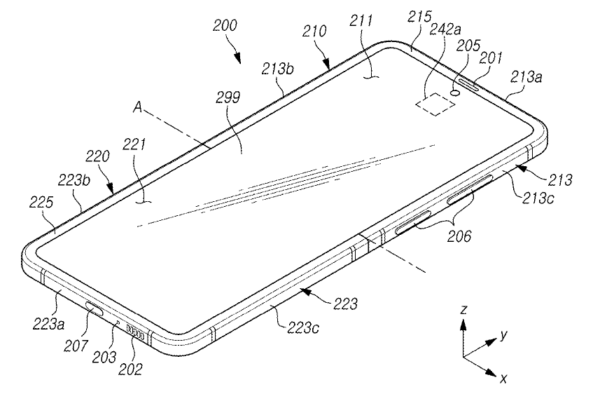

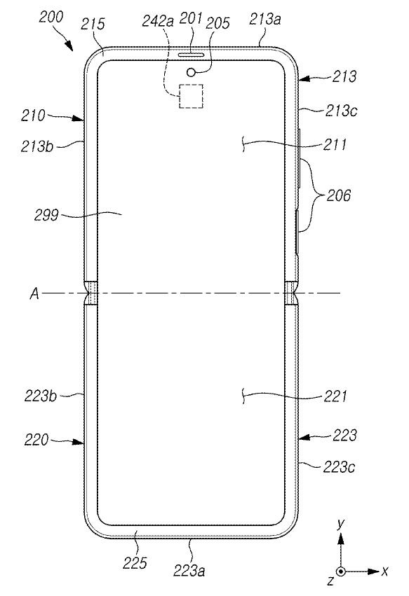

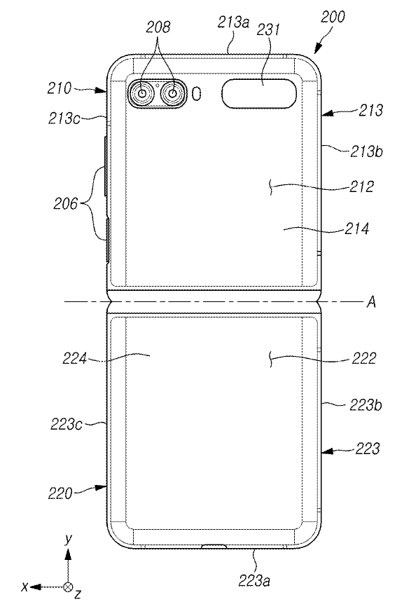

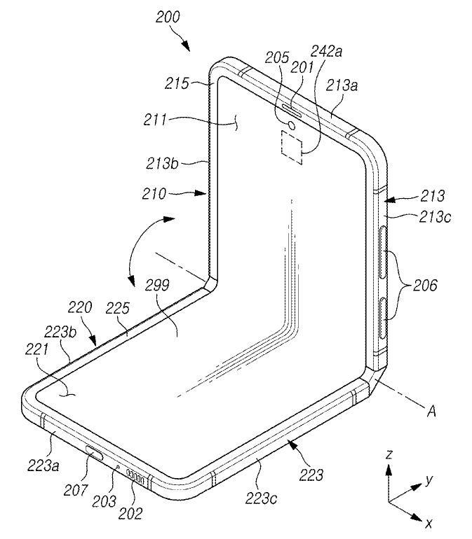

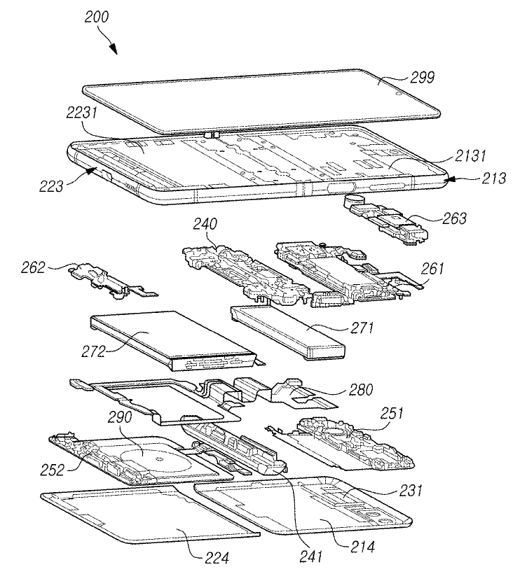

The electronic device to be described below may be understood as illustrating a portable electronic device 200 (e.g., the electronic device 200 of FIG. 2A and below) having an in-folding housing structure. For convenience of description, a rightward direction may be defined as an x-axis direction, and an upward direction may be defined as a y-axis direction, based on a front surface of the electronic device 200 in an unfolded state. Further, a height direction (or a thickness direction) may be defined as a z-axis direction based on the front surface of the electronic device 200 in the unfolded state. However, the above-described directions do not limit positions of elements of the electronic device 200 and may be defined from various perspectives according to an operation state (e.g., an unfolded state, a folded state, or an intermediate state) of the electronic device 200.

FIG. 2A is a front perspective view illustrating an example electronic device 200 in an unfolded (flat or open) state according to various example embodiments.

FIG. 2B is a diagram illustrating a front view of the electronic device 200 in an unfolded state according to various example embodiments.

FIG. 2C is a diagram illustrating a rear view illustrating the electronic device 200 in an unfolded state according to various example embodiments.

FIG. 2D is a perspective view illustrating the electronic device 200 in an intermediate (or partially folded) state viewed from a front direction according to various example embodiments.

Referring to FIGS. 2A to 2D, the electronic device 200 may include a first housing 210, a second housing 220, a hinge assembly 240 connecting the first housing 210 and the second housing 220 such that the second housing 220 is rotatable relative to the first housing 210, a flexible or foldable display 299 disposed within a space formed by the foldable housing 210, 220, and a sensor module (e.g., the sensor module 176 of FIG. 1).

According to an embodiment, the display 299 may be disposed from the first housing 210 across the hinge assembly 240 to the second housing 220. The display 299 may be divided into a first display region 211 disposed in an inner space of the first housing 210 and a second display region 221 disposed in an inner space of the second housing 220 based on a folding axis A. A sensor module (e.g., an illuminance sensor) may be disposed below a sensor region (or light transmitting region) 242a of the first display region 211 in case of being viewed from the front. A position and/or size of the sensor region 242a within the first display region 211 may be determined by a position and/or size of an illuminance sensor disposed therebelow. For example, a size (e.g., a diameter) of the sensor region 242a may be determined based on a field of view (FOV) of the illuminance sensor. In an embodiment, the sensor region 242a may be configured to have a lower pixel density and/or lower line density than surrounding areas for enhanced light transmittance.

According to an embodiment, the hinge assembly 240 may be implemented in an in-folding manner where the two display regions 211, 221 face each other in case that the portable electronic device 200 transitions from an unfolded state (e.g., the state of FIG. 2A) to a folded state (e.g., the state of FIG. 2C). For example, in case that the electronic device 200 is in the unfolded state, the two display regions (e.g., the first display region 211 and the second display region 221) may face substantially the same direction. As a state transition occurs from the unfolded state to the folded state, the two display regions 211, 221 may be rotated in a direction to face each other. The hinge assembly 240 may be configured such that the foldable housing 210, 220 has a resistance force against rotation. In case that an external force exceeding the resistance force is applied to the foldable housing 210, 220, the foldable housing 210, 220 may be rotated.

According to an embodiment, a state of the electronic device 200 may be defined based on an angle formed between the two display regions 211, 221. For example, the state of the electronic device 200 may be defined as an unfolded (flat or open) state in case that the angle between the two display regions 211, 221 is about 180 degrees. In case that the angle between the two display regions 211, 221 is between about 0 degrees and 10 degrees, the state of the portable electronic device 200 may be defined as a folded (or closed) state. In case that the two display regions 211, 221 form an angle (e.g., between about 10 degrees and 179 degrees) greater than the angle in the folded state and smaller than the angle in the unfolded state, the state of the portable electronic device 200 may be defined as an intermediate state (e.g., a partially folded or partially unfolded state) as illustrated in FIG. 2E.

According to an embodiment, the first housing 210 may include, in the unfolded state, a first surface (first display region) 211 facing a first direction (e.g., a front direction) (a z-axis direction) and a second surface 212 facing a second direction (e.g., a rear direction) (-z-axis direction) opposite to the first surface 211. The second housing 220 may include, in the unfolded state, a third surface (second display region) 221 facing the first direction (e.g., the z-axis direction) and a fourth surface 222 facing the second direction (e.g., the -z-axis direction). The electronic device 200 may be operated such that, in the unfolded state, the first surface 211 of the first housing 210 and the third surface 221 of the second housing 220 face the same first direction (e.g., the z-axis direction), and in the folded state, the first surface 211 and the third surface 221 face each other. The electronic device 200 may be operated such that, in the unfolded state, the second surface 212 of the first housing 210 and the fourth surface 222 of the second housing 220 face the same second direction (-z-axis direction), and in the folded state, the second surface 212 and the fourth surface 222 face opposite directions.

According to an embodiment, the first housing 210 may include a first side frame 213 at least partially forming the appearance of the electronic device 200 and a first rear cover 214 coupled with the first side frame 213 and forming at least a portion of the second surface 212 of the electronic device 200. For example, the first side frame 213 may include a first side 213a, a second side 213b extending from one end of the first side 213a, and a third side 213c extending from another end of the first side 213a. For example, the first side frame 213 may be formed in a rectangular (e.g., square or rectangular) shape through the first side 213a, the second side 213b, and the third side 213c. At least a portion of the first side frame 213 may be formed of a conductor.

According to an embodiment, the second housing 220 may include a second side frame 223 at least partially forming an exterior of the electronic device 200 and a second rear cover 224 coupled to the second side frame 223 and forming at least a portion of the fourth surface 222 of the electronic device 200. For example, the second side frame 223 may include a fourth side 223a, a fifth side 223b extending from one end of the fourth side 223a, and a sixth side 223c extending from another end of the fourth side 223a. For example, the second side frame 223 may be formed in a rectangular shape through the fourth side 223a, the fifth side 223b, and the sixth side 223c. At least a portion of the second side frame 223 may be formed of a conductor.

According to an embodiment, the pair of housings 210 and 220 is not limited to the shape and coupling shown but may rather be implemented in other shapes or via a combination and/or coupling of other components. For example, the first side frame 213 may be integrally formed with the first rear cover 214, and the second side frame 223 may be integrally formed with the second rear cover 224.

According to an embodiment, the first rear cover 214 and the second rear cover 224 may be formed by at least one or a combination of, e.g., coated or tinted glass, ceramic, polymer, or metal (e.g., aluminum, stainless steel (STS), or magnesium).

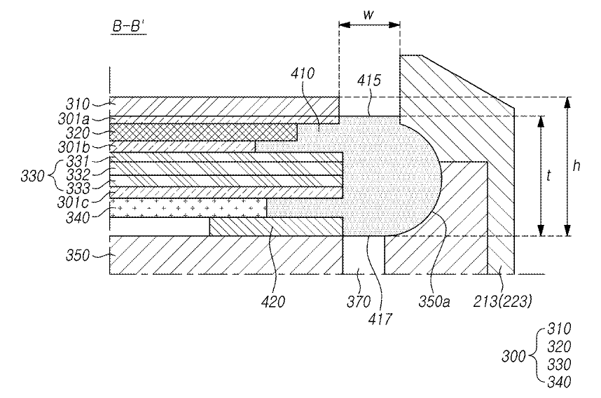

According to an embodiment, the electronic device 200 may include a first cover member 215 (e.g., the first protective member 410 of FIG. 4) disposed along an edge of the first housing 210. The electronic device 200 may include a second cover member 225 (e.g., the first protective member 410 of FIG. 4) disposed along an edge of the second housing 220. For example, the first cover member 215 and the second cover member 225 may be formed of a polymer material.

According to an embodiment, the electronic device 200 may include a sub display 231 disposed separately from the display 299. For example, the sub display 231 may be disposed to be at least partially exposed on the second surface 212 of the first housing 210, and may display state information of the electronic device 200 in the folded state. For example, the sub display 231 may be disposed to be visible from the outside through at least a portion of the first rear cover 214. In various embodiments, the sub display 231 may be disposed on the fourth surface 222 of the second housing 220. In this case, the sub display 231 may be disposed to be visible from the outside through at least a partial area of the second rear cover 224.

According to an embodiment, the electronic device 200 may include at least one of an input device 203, an acoustic output device 201, 202, a camera module 205, 208, a key input device 206, a connector port 207, and a sensor module (not illustrated). In an embodiment, a sensor module (e.g., the sensor module 176 of FIG. 1) and a camera 205 may be disposed below the display 299 in case of being viewed from the front.

According to an embodiment, the electronic device 200 may be operated to maintain an intermediate state through the hinge assembly 240. In this case, the electronic device 200 may control the display 299 such that different content is displayed in a display region corresponding to the first surface 211 and a display region corresponding to the third surface 221.

FIG. 2E is an exploded perspective view illustrating the electronic device 200 according to various example embodiments.

Referring to FIG. 2E, the electronic device 200 may include a first side frame 213, a second side frame 223, and a hinge assembly 240 rotatably connecting the first side frame 213 and the second side frame 223. For example, the electronic device 200 may include a first support plate 2131 at least partially extending from the first side frame 213 and a second support plate 2231 at least partially extending from the second side frame 223. For example, the first support plate 2131 may be integrally formed with the first side frame 213 or structurally coupled to the first side frame 213. Similarly, the second support plate 2231 may be integrally formed with the second side frame 223 or may be structurally coupled with the second side frame 223. For example, the electronic device 200 may include a display 299 disposed to be supported by the first support plate 2131 and the second support plate 2231. For example, the electronic device 200 may include a first rear cover 214 coupled to the first side frame 213 and providing a first space between the first rear cover 214 and the first support plate 2131, and a second rear cover 224 coupled to the second side frame 223 and providing a second space between the second rear cover 224 and the second support plate 2231. In an embodiment, the first side frame 213 and the first rear cover 214 may be integrally formed. In an embodiment, the second side frame 223 and the second rear cover 224 may be integrally formed. For example, the electronic device 200 may include a first housing 210 provided through the first side frame 213, the first support plate 2131, and the first rear cover 214. For example, the electronic device 200 may include a second housing 220 provided through the second side frame 223, the second support plate 2231, and the second rear cover 224.

According to an embodiment, the hinge assembly 240 may include a first arm structure coupled to the first housing 210 (e.g., the first support plate 2131), a second arm structure coupled to the second housing 220 (e.g., the second support plate 2231), and a detent structure physically contacting the first arm structure and the second arm structure such that the first housing 210 and the second housing 220 have a resistance force against rotation. The foldable housing 210, 220 may have a resistance force against rotation due to a contact force (e.g., a force pushing the first arm structure and the second arm structure) of the detent structure.

According to an embodiment, the electronic device 200 may include a first board assembly 261 (e.g., a main printed circuit board), a camera assembly 263, a first battery 271, or a first bracket 251 disposed in a first space between the first side frame 213 and the first rear cover 214. For example, the camera assembly 263 may include a plurality of cameras (e.g., the camera modules 205, 208 of FIGS. 2A and 2C) and may be electrically connected to the first board assembly 261. For example, the first bracket 251 may provide a support structure and enhanced rigidity for supporting the first board assembly 261 and/or the camera assembly 263. For example, the electronic device 200 may include a second board assembly 262 (e.g., a sub printed circuit board), an antenna 290 (e.g., a coil member), a second battery 272, or a second bracket 252 disposed in the second space between the second side frame 223 and the second rear cover 224. For example, the electronic device 200 may include a line member 280 (e.g., a flexible printed circuit board (FPCB)) extending from the first board assembly 261 across the hinge assembly 240 to a plurality of electronic components (e.g., the second board assembly 262, the second battery 272, or the antenna 290) disposed between the second side frame 223 and the second rear cover 224, and providing an electrical connection.

According to an embodiment, the electronic device 200 may include a hinge cover 241 supporting the hinge assembly 240, exposed to the outside in case that the electronic device 200 is in the folded state, and disposed not to be visible from the outside by being retracted into the first space and the second space in case that it is in the unfolded state.

According to an embodiment, the electronic device 200 may include a first cover member 215 coupled along an edge of the first side frame 213. For example, the electronic device 200 may include a second cover member 225 coupled along an edge of the second side frame 223. In the display 299, an edge of the first display region 211 may be protected by the first cover member 215. An edge of the second display region 221 may be protected by the second cover member 225.

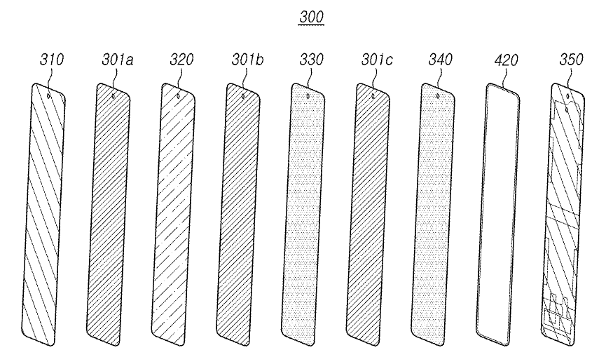

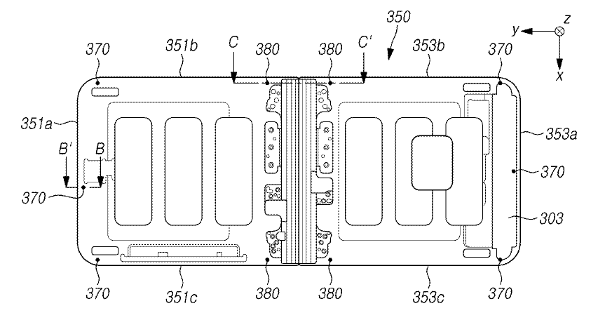

Hereinafter, a first protective member (e.g., the first protective member 410 of FIG. 4) disposed between the display 299 of the electronic device 200 and a side frame (e.g., the first side frame 213 and the second side frame 223) and a second protective member (e.g., the second protective member 420 of FIG. 3A) disposed along a periphery of a rear surface of the display 299 is mainly described. The display 299 is supported by the first support plate 2131 and the second support plate 2231, and a side surface of the display 299 and the side frames 213, 223 may be disposed with a predetermined distance therebetween, which may be referred to as a gap (or may be referred to as an assembly gap or assembly clearance). The gap may be provided to secure a space for slip occurring as the display 299 repeatedly folds and unfolds. The gap may be set to about 0.5 mm or more. Accordingly, a predetermined particulate foreign object (or impurity) may penetrate through the gap and be introduced into a side surface of the display 299 or an interior of the electronic device 200. The foreign object (or impurity) may damage a display panel (e.g., the display panel 330 of FIG. 3A) or cause scratches on each layer of the display 299. Accordingly, the first protective member 410 and the second protective member 420 may block foreign objects from being introduced (or penetrating) into a side surface and/or rear surface of the display 299.

FIG. 3A is an exploded perspective view illustrating an example flexible display 300 according to various example embodiments. For convenience of description, the z-axis direction in the drawings, which is a direction in which image information of the flexible display 300 is displayed, may be referred to as an upward direction, an upper portion, or an upper surface, and directions perpendicular to the z-axis may be referred to as a lateral direction, a lateral portion, or a side surface.

Referring to FIG. 3A, the flexible display 300 (e.g., the display 299 of FIG. 2) may include a protective layer 310, a cover window 320, a display panel 330, and a rear cover 340. The protective layer 310 may be a layer protecting the flexible display 300 from contamination, scratches, and external physical damage. For example, the protective layer 310 may include a synthetic resin film such as PET or polyurethane.

According to an embodiment, the cover window 320 may be a layer providing rigidity to a front surface of the display panel 330 and protecting the display panel 330 from external forces such as punctures or dents. For example, the cover window 320 may include a transparent polymer material such as colorless polyimide and/or an ultra-thin glass material. The ultra-thin glass may have a predetermined thickness to maintain flexibility. The ultra-thin glass may have, e.g., a thickness of 100 micrometers or less.

According to an embodiment, the display panel 330 may be a region displaying image information. The display panel 330 may include an AMOLED or a similar electroluminescent display. In various embodiments, the display panel 330 may include a polarizing film 331, a panel region 332, and a plastic film 333. The panel region 332 may include, e.g., a plurality of light emitting elements such as AMOLED, electrodes supplying power to the light emitting elements, and a control circuit. The polarizing film 331 is located on an upper portion of the panel region 332 and may reduce visibility degradation due to reflected light by polarizing light emitted from the panel region 332 and reflected light reflected from a rear surface of the panel region 332. The plastic film 333 may include a substrate for forming the panel region 332. The plastic film 333 may include a substrate of a synthetic resin material capable of providing flexibility to the display panel 330. For example, the display panel 330 may include a touch screen panel (not illustrated).

According to an embodiment, a support housing 350 may help reinforce rigidity of the electronic device, shield ambient noise generated from other components of the electronic device, and may be used to dissipate heat generated during operation of the display panel 330. The support housing 350 may provide a predetermined space where the flexible display 300 is seated. The support housing 350 may include a metal material. Since metal has electrical conductivity and thermal conductivity, it may be effective for noise shielding and heat dissipation. The metal may include stainless steel, aluminum, copper, or a composite thereof (e.g., a member in which dissimilar metals are laminated in a plate shape). In various embodiments, the support housing 350 may include a lattice plate structure capable of being bent following a bending operation of the flexible display 300 and mechanically supporting components of the flexible display 300.

According to an embodiment, a portion of the support housing 350 may be structurally coupled to a side frame (e.g., the first side frame 213 and the second side frame 223). For example, an inner side of the side frames 213, 223 and a side surface of the support housing 350 may be physically coupled in a state in which they contact each other. For example, the side frames 213, 223 and the support housing 350 may be integrally formed. The flexible display 300 may be disposed on a front side of a structure integrally formed by the side frames 213, 223 and the support housing 350.

According to an embodiment, the support housing 350 may include a plurality of holes (e.g., the first hole 370 and the second hole 380 of FIG. 3B). The plurality of holes 370, 380 may include a first hole 370 and a second hole 380. The first hole 370 may form an inlet through which the first protective member (e.g., the first protective member 410 of FIG. 4) is injected. The first hole 370 may be referred to as an "injection hole." The second hole 380 may form an inlet through which a light source is transmitted for partially curing the first protective member 410. The second hole 380 may be referred to as a "light source irradiation hole." The plurality of holes 370, 380 is described with reference to FIG. 3B.

According to an embodiment, the second protective member 420 may be disposed between the support housing 350 and the display panel 330. The second protective member 420 may be disposed along at least a portion of an edge in a rear surface direction of the display panel 330. The second protective member 420 may close a region (e.g., a gap having a predetermined thickness) formed between the support housing 350 and the display panel 330. Accordingly, the second protective member 420 may prevent and/or block the first protective member 410 from penetrating between the flexible display 300 and the support housing 350 in case that the liquid first protective member 410 is injected.

For example, the second protective member 420 may be located along at least a portion of an edge of a rear surface of the display panel 330. The second protective member 420 may be disposed except for a region where an adhesive member (e.g., a first adhesive layer 301a) is provided among edges of the rear surface of the display panel 330.

For example, the second protective member 420 may be located along an entire edge of the rear surface of the display panel 330.

According to an embodiment, the second protective member 420 may be formed of a pressure sensitive adhesive (PSA), but the disclosure is not limited thereto. For example, the second protective member 420 may have a predetermined tackiness (e.g., tack) at room temperature and may be formed of a material having a solid or semi-solid state at room temperature. The second protective member 420 may be implemented as, e.g., a double-sided tape having a predetermined tackiness. The second protective member 420 may be used interchangeably with an adhesive member (e.g., the first to third adhesive layers 301a, 301b, 301c).

According to an embodiment, the second protective member 420 may have various widths, lengths, and thicknesses corresponding to regions of the flexible display 300. For example, in case that a gap in a predetermined region of the flexible display 300 to which the second protective member 420 is applied is relatively larger than surrounding regions, a thickness of the second protective member 420 applied in the predetermined region may be relatively larger.

According to an embodiment, at least a portion of the second protective member 420 may be disposed corresponding to a region where chip on plastic (COP) is provided. The COP may include a flexible substrate on which a driving circuit including a display driver IC (DDI) for driving the flexible display 300 is located. A COP bending portion may be applied to a region where the COP is bent or folded to a lower portion of the flexible display 300 to electrically connect the driving circuit and a printed circuit board (e.g., the first board assembly 261 and/or the second board assembly 262 of FIG. 2E) of the electronic device. In this case, the second protective member 420 may cover at least a portion of a region where the COP is disposed.

According to an embodiment, the flexible display 300 may include at least one adhesive layer 301a, 301b, 301c bonding at least two or more layers among the protective layer 310, the cover window 320, the display panel 330, the rear cover 340, and the support housing 350 to each other. For example, the flexible display 300 may include a first adhesive layer 301a bonding the protective layer 310 and the cover window 320, a second adhesive layer 301b bonding the cover window 320 and the panel, and a third adhesive layer 301c bonding the panel region 332 and the rear cover 340.

For example, the adhesive layers 301a, 301b, 301c may include a pressure sensitive adhesive (PSA). In order to provide bending performance of the flexible display 300, slip may occur between a plurality of layers included in the flexible display 300. Accordingly, in case that each layer is bonded with a pressure sensitive adhesive having a low shear modulus and a high elastic limit, the plurality of layers of the flexible display 300 may slip relative to each other while maintaining a bonded state by the PSA. Further, the adhesive layers 301a, 301b, 301c may include a transparent adhesive such as optical clear adhesive (OCA), optical clear resin (OCR), or super view resin (SVR).

FIG. 3B is a diagram illustrating a rear view of the flexible display 300 viewed from a rear surface direction (e.g., the -z-axis direction) according to various example embodiments. Accordingly, FIG. 3B may be understood as a rear view illustrating the support housing 350 viewed from the rear surface direction.

Referring to FIG. 3B, the support housing 350 may secure rigidity of the flexible display 300. The support housing 350 may be formed of at least one or a combination of metal and plastic.

According to an embodiment, the support housing 350 may include a first side 351acorresponding to a first side (e.g., the first side 213a of FIG. 2A) of a first side frame (e.g., the first side frame 213 of FIG. 2A). The support housing 350 may include a second side 351bconnected to one end of the first side 351a and a third side 351c connected to another end of the first side 351a. The support housing 350 may include a fourth side 353a corresponding to a fourth side (e.g., the fourth side 223a of FIG. 2A) of a second side frame (e.g., the second side frame 223 of FIG. 2A). The support housing 350 may include a fifth side 353b connected to one end of the fourth side 353a and a sixth side 353c connected to another end of the fourth side 353a.

According to an embodiment, the support housing 350 may include a COP seating portion 303. The COP seating portion 303 may be understood as a predetermined region corresponding to the support housing 350 in case that the COP is bent and covers one surface of the support housing 350.

According to an embodiment, the support housing 350 may include a plurality of holes 370, 380. The plurality of holes 370, 380 may be disposed along a side edge of the support housing 350.

According to an embodiment, the plurality of holes 370, 380 may have a circular or elliptical shape. For example, in case that the plurality of holes 370, 380 are implemented in a circular shape, they may have a diameter of 0.3 mm to 3 mm. For example, in case that the plurality of holes 370, 380 are implemented in an elliptical shape, they may have a major axis of 0.3 mm to 3 mm.

According to an embodiment, the plurality of holes 370, 380 may include a first hole 370 and a second hole 380. The first hole 370 may form an inlet for filling the liquid first protective member 410. The second hole 380 may form an inlet for a light source to be transmitted for curing the first protective member 410. The first hole 370 and the second hole 380 may each be provided in plural numbers.

According to an embodiment, the first hole 370 may be disposed near the first side 351a and the fourth side 353a of the support housing 350.

According to an embodiment, the first hole 370 may be disposed considering a position of an electrical component (e.g., a camera module or a connector) included in the electronic device 200. The first hole 370 may be disposed to minimize and/or reduce interference with the electrical component. For example, in case that the electrical component is mounted near a center of the first side 351a, the first hole 370 may be disposed near one end and/or another end of the first side 351.

According to an embodiment, the liquid first protective member 410 may be cured by a light source (e.g., ultraviolet light) radiated from a front surface and a rear surface of the flexible display 300. Due to a repulsive force generated during folding by the cured first protective member 410, the first protective member 410 disposed near a folding axis (e.g., the folding axis A of FIG. 2A) may interfere with a folding operation of the flexible display 300. Accordingly, a thickness of the first protective member 410 needs to decrease as it becomes adjacent to the folding axis A.

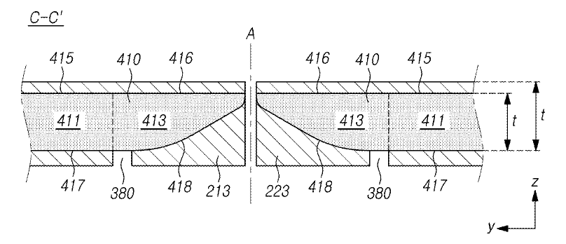

According to an embodiment, by irradiating a light source through the second hole 380, the first protective member 410 near the folding axis A may be partially cured. Accordingly, the thickness of the first protective member 410 may decrease as it becomes closer to the folding axis A. This is described with reference to FIG. 5.

According to an embodiment, the second hole 380 may be disposed near the folding axis A of the second side 351b, the third side 351c, the fifth side 353b, and the sixth side 353c of the support housing 350.

FIG. 4 is an enlarged partial cross-sectional view illustrating a portion of the flexible display 300 and a housing (e.g., the side frames 213, 223) according to various example embodiments. FIG. 4 may be understood as a cross-sectional view taken along line B-B' in FIG. 3B.

Referring to FIG. 4, the flexible display 300 may be supported by a support plate (e.g., the first support plate 2131 and the second support plate 2231 of FIG. 2E). The flexible display 300 may be seated in a space formed by the side frames 213, 223. In order to provide slip during bending of the flexible display 300, a gap having a predetermined distance may be present between a space formed by the side frames 213, 223 and the support plates 2131, 2231 and a side surface of the flexible display 300. For example, the gap may have a predetermined width w. The predetermined width w may be implemented at, e.g., about 0.5 mm. Because a plurality of layers included in the flexible display 300 have different lengths or widths, the predetermined width w may differ corresponding to a height.

According to an embodiment, the first protective member 410 may block foreign objects from intruding through the gap. The first protective member 410 may be disposed between a side surface of the flexible display 300 and the side frames 213, 223. The first protective member 410 may tightly contact a region including a space formed between the side surface of the flexible display 300 and the side frames 213, 223. Accordingly, the first protective member 410 may close a path through which foreign objects are introduced into the gap.

According to an embodiment, the first protective member 410 may include a polymer material. Because the first protective member 410 is formed of a polymer material, in case that the flexible display 300 is bent, the first protective member 410 may be bent following the bending operation of the flexible display 300 while maintaining a tight contact state with a region on a side surface of the flexible display. During bending of the flexible display 300, a plurality of layers (e.g., the cover window 320 or the display panel 330 of FIG. 3A) included in the flexible display 300 may be bent at different curvatures while causing slip therebetween. The polymer material of the first protective member 410 may have elasticity and elongation capable of being bent while maintaining a tight contact state with the plurality of layers of the flexible display 300 as described above.

According to an embodiment, the first protective member 410 may be formed of a polymer material having a predetermined permittivity and a predetermined dielectric loss. The permittivity of the polymer material may be, e.g., 3.5 or less. The dielectric loss of the polymer material may be 0.02 or less. By the polymer material having a predetermined permittivity and a predetermined dielectric loss, degradation of antenna performance of the side frames 213, 223 formed of a metal material may be minimized and/or reduced.

According to an embodiment, the first protective member 410 being in tight contact may be understood as the first protective member 410 being bonded and/or attached. For example, the first protective member 410 may be bonded to a region including a space between the cover window 320 and the display panel 330 on a side surface of the flexible display 300. For example, the first protective member 410 may be filled in a region including a space between the cover window 320 and the display panel 330 on a side surface of the flexible display 300 by viscosity of the polymer material.

According to an embodiment, the first protective member 410 may tightly contact a region including a space between a lower portion of the protective layer 310 and an upper surface of the display panel 330. A gap may be present in this region to allow slip between the protective layer 310 and the cover window 320. The first protective member 410 may tightly contact the region where the gap is present, thereby reducing damage to the display panel 330 or cover glass caused by foreign objects being introduced during a bending operation.

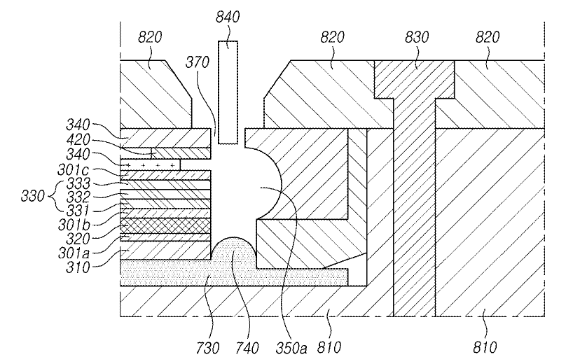

According to an embodiment, the first protective member 410 may be injected through the first hole 370 (e.g., the first hole 370 of FIG. 3B). An injection device (e.g., the dispensing nozzle 840 of FIG. 8) may inject the liquid first protective member 410 through the first hole 370. The liquid first protective member 410 may be injected through the first hole 370 and flow along a path between the flexible display 300 and the side frames 213, 223 and fill the space forming the gap. For example, in order for the first protective member 410 to have a predetermined fluidity in a liquid state, the first protective member 410 may be formed of a flexible material having low viscosity and high stretchability.

For example, the first protective member 410 may have, e.g., a predetermined viscosity. The first protective member 410 may have, e.g., a viscosity of 1,000 to 10,000 cPs in a solution state.

According to an embodiment, the first protective member 410 may have a predetermined elasticity and a predetermined elongation.

According to an embodiment, a polymer material may be injected through the first hole 370 into the gap between the flexible display 300 and the side frames 213, 223. A solution of the polymer material may be injected by a spraying process such as jetting or dispensing. Thereafter, the polymer material may be cured by one or at least two or more curing methods among light curing by a light source, thermal curing by heat, room temperature curing, or moisture curing.

According to an embodiment, a polymer material of the first protective member 410 may be introduced through the first hole 370 and flow along a side edge of the flexible display 300. In order for the introduced polymer material to flow easily, a portion of an inner side of the side frames 213, 223 facing a side surface of the flexible display 300 may be curved, and this may be referred to as a flow groove 350a. Due to the flow groove 350a, the polymer material may easily move along a path formed by a gap near an edge of the electronic device 200.

According to an embodiment, the flow groove 350a may be formed on at least a portion of the path formed by the gap. For example, the flow groove 350a may be formed only near the first hole 370, may be formed at a point where the width of the path narrows, or may be formed throughout the entire path. The flow groove 350a may be formed considering fluidity of the polymer material itself and flow resistance of the polymer material flowing in the path.

According to an embodiment, the first protective member 410 may have a first surface 415 corresponding to a front surface of the flexible display 300 and a second surface 417 corresponding to a rear surface of the flexible display 300. A thickness t of the first protective member 410 may be defined as a distance between the first surface 415 and the second surface 417.

According to an embodiment, the second surface 417 of the first protective member 410 may be determined by a volume of the polymer material injected through the first hole 370. For example, the second surface 417 may be located at substantially the same height as a lower surface of the second protective member 420.

According to an embodiment, a height or shape of the first surface 415 of the first protective member 410 may be determined by a coupling protrusion 740 disposed on a seating pad 700 to be described below. The height of the first surface 415 may be determined by the height of the coupling protrusion 740 disposed on the seating pad 700. The shape of the first surface 415 may be determined by the shape of the coupling protrusion 740 disposed on the seating pad 700. For example, the first surface 415 may be flat or curved toward a rear surface direction. This is described in greater detail below with reference to FIG. 8.

According to an embodiment, the first surface 415 of the first protective member 410 may be located relatively lower than or at the same height as a topmost portion of the flexible display 300. In other words, the thickness t of the first protective member 410 may be less than or equal to a thickness h of the flexible display 300 and the second protective member 420. The relationship between t and h may be defined as follows: 1/2h≤t≤h

According to an embodiment, in case that the first surface 415 of the first protective member 410 is located relatively lower than the topmost portion of the flexible display 300, the first protective member 410 may block foreign objects from being introduced into the gap while securing a space required to allow slip occurring in the flexible display 300.

According to an embodiment, the height t of the first protective member 410 may be determined considering a degree of deformation due to slip in the flexible display 300. For example, in a region where the degree of deformation due to slip in the flexible display 300 is large, the height of the first protective member 410 may be lowered.

For example, the first surface 415 may be located at substantially the same height as a lower surface of the protective layer 310. The first protective member 410 may be disposed to correspond to a height up to an upper surface of the cover window 320 on a side surface of the flexible display 300.

For example, the first surface 415 may be located at substantially the same height as an ultra-thin glass included in the cover window 320.

According to an embodiment, the second protective member 420 may be provided to prevent and/or reduce a polymer material of the first protective member 410 from flowing and penetrating into a rear surface of the flexible display 300. The second protective member 420 may be disposed along an edge of the rear surface of the flexible display 300.

According to an embodiment, the second protective member 420 may be disposed between the support housing 350 and the display panel 330. The second protective member 420 may be disposed along an edge in a rear surface direction of the display panel 330. The second protective member 420 may close a region (e.g., a gap having a predetermined thickness) formed between the support housing 350 and the display panel 330. Accordingly, the second protective member 420 may prevent and/or block the first protective member 410 from penetrating between the flexible display 300 and the support housing 350 in case that the liquid first protective member 410 is injected.

According to an embodiment, the second protective member 420 may be formed of PSA, but the disclosure is not limited thereto. For example, the second protective member 420 may have a predetermined tackiness (e.g., tack) at room temperature and may be formed of a material having a solid or semi-solid state at room temperature. The second protective member 420 may be implemented as, e.g., a double-sided tape having a predetermined tackiness. The second protective member 420 may be used interchangeably with an adhesive member (e.g., the first to third adhesive layers 301a, 301b, 301c).

According to an embodiment, the second protective member 420 may have various widths, lengths, and thicknesses corresponding to regions of the flexible display 300. For example, in case that a step in a predetermined region of the flexible display 300 to which the second protective member 420 is applied is relatively larger than surrounding regions, a thickness of the second protective member 420 applied in the predetermined region may be relatively larger.

FIG. 5 is an enlarged partial cross-sectional view illustrating a portion of the first protective member 410 and a housing (e.g., the side frames 213, 223) according to various example embodiments. FIG. 5 may be understood as a cross-sectional view taken along C-C' in FIG. 3B.

Referring to FIG. 5, the first protective member 410 may be symmetric on two opposite sides based on the folding axis A (e.g., the folding axis A of FIG. 2A).

According to an embodiment, the first protective member 410 may have a substantially uniform thickness. However, the first protective member 410 may have a decreased thickness near a folding region. The first protective member 410 may include a 1-1th protective member 413 located near the folding region. The first protective member 410 may include a 1-2th protective member 411 adjacent to the 1-1th protective member 413.

According to an embodiment, the 1-1th protective member 413 may include a first surface 416 corresponding to a front surface of the flexible display 300. The 1-1th protective member 413 may include a second surface 418 corresponding to a rear surface of the flexible display 300.

According to an embodiment, the 1-2th protective member 411 may include a first surface 415 corresponding to a front surface of the flexible display 300. The first surface 415 may be substantially identical to the first surface 415 of the first protective member 410. The 1-2th protective member 411 may include a second surface 417 corresponding to a rear surface of the flexible display 300. The second surface 417 may be substantially identical to the second surface 417 of the first protective member 410.

According to an embodiment, due to a repulsive force of a polymer material of the first protective member 410, the first protective member 410 near the folding region may degrade folding performance of the electronic device 200. Accordingly, the first protective member 410 may be disposed to reduce a region occupied near the folding region.

For example, the 1-1th protective member 413 may not be present in a region corresponding to the folding axis A. In other words, a space formed by the gap may be empty in this region.

According to an embodiment, the 1-1th protective member 413 may have a decreased thickness as it becomes adjacent to the folding axis A. The 1-1th protective member 413 may have a decreased thickness such that the height of the first surface 416 is constant and the second surface 418 approaches the first surface 416 as the second surface 418 becomes adjacent to the folding axis A. Accordingly, in case of viewing the electronic device 200 from the front, the first protective member 410 appears to extend to the folding region, thereby providing aesthetics.

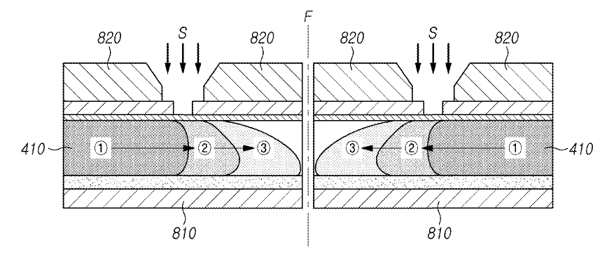

According to an embodiment, the height of the second surface 418 of the 1-1th protective member 413 may be controlled by a light source radiated through the second hole 380 (e.g., the second hole 380 of FIG. 3B). In case that a light source for curing the 1-1th protective member 413 is radiated through the second hole 380, the 1-1th protective member near the second hole 380 is partially cured, and the second surface 418 may be disposed to be inclined. This is described in greater detail below with reference to FIG. 9.

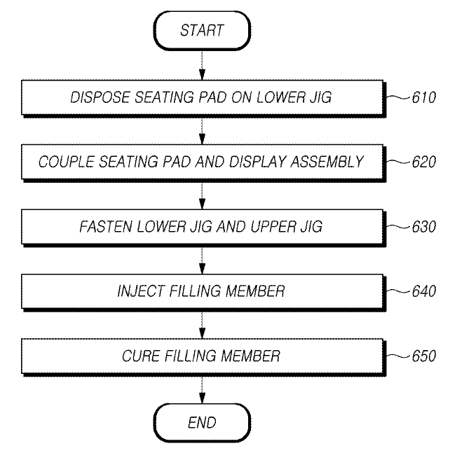

FIG. 6 is a flowchart illustrating an example manufacturing process for filling the first protective member 410 in a gap formed between the flexible display 300 and a housing (e.g., the side frames 213, 223) according to various example embodiments.

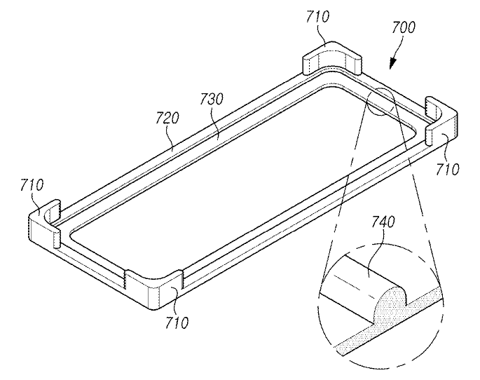

Referring to FIG. 6, in step 610, a seating pad (e.g., the seating pad 700 of FIG. 7) may be disposed on a lower jig (e.g., the lower jig 810 of FIG. 8). A space where the seating pad 700 is to be provided may be formed in the lower jig 810. The space may be at least partially recessed or cut so that the seating pad 700 may be disposed. The seating pad 700 may be fixed in the space.

According to an embodiment, in step 620, a display assembly may be coupled to the seating pad 700. The display assembly may refer, for example, to a structure in which the flexible display 300 and the side frames 213, 223 are partially coupled, and may be understood as a semi-assembled structure of the electronic device 200 for filling the first protective member 410.

According to an embodiment, the display assembly may be coupled such that a front surface (e.g., a front surface of the flexible display 300) of the display assembly faces the seating pad 700. In case that the display assembly and the seating pad 700 are assembled, a coupling protrusion 740 provided on a seating portion (e.g., the seating portion 730 of FIG. 7) of the seating pad 700 may be coupled to a gap formed along an edge of the flexible display 300.

According to an embodiment, in step 630, the lower jig 810 and an upper jig (e.g., the upper jig 820 of FIG. 8) may be fastened. With the display assembly disposed between the lower jig 810 and the upper jig 820, they may be fastened by a fastening member (e.g., the fastening member 830 of FIG. 8). According to an embodiment, the upper jig 820 may include a plurality of holes. With the lower jig 810 and the upper jig 820 fastened, the plurality of holes may be positioned to correspond to the first hole 370 and the second hole 380.

According to an embodiment, in step 640, a filling member may be injected. The filling member may be, e.g., a liquid polymer material of the first protective member 410. The polymer material may be sprayed from an injection nozzle (e.g., the injection nozzle 840 of FIG. 8), pass through a hole provided in the upper jig 820, and be introduced through the first hole 370. The polymer material may flow through a path formed by the gap.

According to an embodiment, in step 650, the filling member may be cured. The liquid polymer material may be cured by a light source, a heat source, or moisture radiated from a front surface direction or a rear surface direction of the jig. As the polymer material is cured near the second hole 380, one surface (e.g., the second surface 418 of FIG. 5) of the first protective member 410 may be disposed to be inclined, and the thickness of the first protective member 410 may decrease.

FIG. 7 is a perspective view illustrating an example seating pad 700 according to various example embodiments.

Referring to FIG. 7, the seating pad 700 may guide the display assembly to facilitate filling of the first protective member 410. The display assembly is a state in which the flexible display 300 and a portion of the side frames 213, 223 are coupled, and may be understood as a semi-assembled electronic device 200 for filling the first protective member 410 in a gap formed between the flexible display 300 and the side frames 213, 223.

According to an embodiment, a front surface of the display assembly may be coupled to face the seating pad 700.

According to an embodiment, the seating pad 700 may be formed of a flexible material having low hardness and high stretchability in order to secure airtightness with the display assembly. For example, the seating pad 700 may be formed of silicone, urethane, or rubber.

According to an embodiment, in order for a light source (e.g., UV) for curing the first protective member 410 to transmit through the seating pad 700, the seating pad 700 may be formed of a material having a predetermined light transmittance. The predetermined light transmittance may have, e.g., an optical density value of 1 or less.

According to an embodiment, the seating pad 700 may include a seating portion 730, a frame 720 surrounding an outer edge of the seating portion 730, and a fixing guide 710 for fixing corners of the display assembly.

According to an embodiment, the fixing guide 710 may be disposed at four corners of the seating pad 700. A height of the fixing guide 710 may be substantially identical to a height of the display assembly.

According to an embodiment, the frame 720 may fix the display assembly to the seating pad 700. An inner side of the frame 720 may correspond to an outer edge of the side frames 213, 223 included in the display assembly.

According to an embodiment, the seating portion 730 may provide a region where at least a portion of a front surface of the display assembly is seated.

According to an embodiment, the seating portion 730 may include a coupling protrusion 740. The coupling protrusion 740 may be coupled to the gap of the display assembly. The shape of the first surface 415 of the first protective member 410 may be determined according to the shape of the coupling protrusion 740.

According to an embodiment, a cross-section of the coupling protrusion 740 may be formed in a circular shape, an elliptical shape, a rectangular shape, or the like, and may be implemented in a plurality of steps to achieve higher adhesion in case of being seated with the front surface of the display assembly.

According to an embodiment, a barrier structure may be provided in a predetermined region of the seating portion 730 corresponding to the folding region of the flexible display 300. The barrier structure may block the first protective member 410 from overflowing in the folding region. The barrier structure may be formed, e.g., at a point corresponding to the folding axis A of the flexible display 300.

FIG. 8 is a partial cross-sectional view illustrating a display assembly fixed to a jig device according to various example embodiments. FIG. 8 illustrates step 640 of FIG. 6, and may be understood as a cross-sectional view near the first hole 370 included in the electronic device 200.

Referring to FIG. 8, a seating pad (e.g., the seating pad 700 of FIG. 7) may be disposed on an upper side of the lower jig 810. A display assembly may be coupled to an upper side of the seating pad 700. In case that the seating pad 700 and the display assembly are coupled, the coupling protrusion 740 included in the seating pad 700 may be coupled to a gap formed along a side edge of the flexible display 300. The coupling protrusion 740 is substantially in tight contact with the gap, and the height or shape of the first surface 415 of the first protective member 410 may be uniformly disposed. The shape of the first surface 415 of the first protective member 410 may be determined according to the shape of the coupling protrusion 740.

According to an embodiment, a liquid polymer material may be introduced from the injection nozzle 840 and sprayed into a gap formed on an edge of the flexible display 300.

According to an embodiment, the flow groove 350a may provide a wide flow path for easy flow of the liquid polymer material. The flow groove 350a may be formed by curving a portion of an inner side of the side frames 213, 223 facing a side surface of the flexible display 300.

According to an embodiment, the flow groove 350a may be formed on at least a portion of the path formed by the gap. For example, the flow groove 350a may be formed only near the first hole 370, may be formed at a point where the width of the path narrows, or may be formed throughout the entire path. The flow groove 350a may be formed considering fluidity of the polymer material itself and flow resistance of the polymer material flowing in the path.

FIG. 9 is a partial cross-sectional view illustrating a display assembly fixed to a jig device according to various example embodiments. FIG. 9 illustrates step 650 of FIG. 6, and may be understood as a cross-sectional view illustrating a vicinity of the second hole 380 included in the electronic device 200.

Referring to FIG. 9, the first protective member 410 may be formed by curing a liquid polymer material. The liquid polymer material may flow along the folding axis A. For example, the polymer material may flow in the order of ①, ②, and ③.

According to an embodiment, UV light S may be radiated through the second hole 380. The first protective member 410 closer to the second hole 380 may be cured faster and have a slower flow speed. Accordingly, the second surface (e.g., the second surface 418 of FIG. 5) of the first protective member 410 adjacent to the second hole 380 may be disposed to be inclined with respect to the first surface (e.g., the first surface 416 of FIG. 5).

According to an embodiment, the first protective member 410 may be cured not only by a light source but also by heat source curing, room temperature curing, or wet curing.

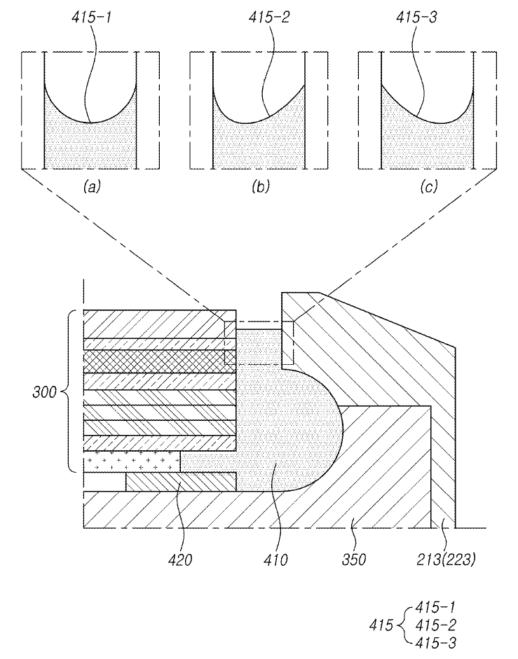

FIG. 10 is a diagram illustrating an example shape of the first surface 415 of the first protective member 410 according to various embodiments.

Referring to FIG. 10, the first surface 415 of the first protective member 410 may be determined by the shape of the coupling protrusion 740 provided on a seating pad (e.g., the seating pad 700 of FIG. 7).

According to an embodiment, the first surface 415 may be flat or curved. In case that the first surface 415 is curved, the first surface 415 may be curved toward a rear surface direction.

For example, in case that the first surface 415 is curved, the first surface 415-1 of the first protective member 410 may be curved symmetrically left and right.

For example, in case that the first surface 415 is curved, the first surface 415-2 of the first protective member 410 may be curved inclined to the left.

For example, in case that the first surface 415 is curved, the first surface 415-3 of the first protective member 410 may be curved inclined to the right.

An electronic device 101, 200 according to an example embodiment of the disclosure may include a first housing 213, a second housing 223, a hinge assembly 240 including a hinge disposed between the first housing 213 and the second housing 223 and rotatably coupling the first housing 213 and the second housing 223, a flexible display 299, 300 including a first region 211 corresponding to the first housing 213, a second region 221 corresponding to the second housing 223, and a folding region corresponding to the hinge assembly 240 and connecting the first region 211 and the second region 221, and a protective member 410, 420 disposed on at least a portion of a periphery of the flexible display 299, 300. The protective member 410, 420 may include a first protective member 410 comprising a polymer disposed between an edge of the flexible display 299, 300 and a side wall of the first housing 213, and/or disposed between an edge of the flexible display 299, 300 and a side wall of the second housing 223, and a second protective member 420 comprising an adhesive at least partially disposed between a rear surface of the flexible display 299, 300 and an inner wall of the first housing 213, and/or at least partially disposed between a rear surface of the flexible display 299, 300 and an inner wall of the second housing 223.

In the electronic device 101, 200 according to an example embodiment of the disclosure, at least a portion of the second protective member 420 may be disposed on an outer periphery of the rear surface.

In the electronic device 101, 200 according to an example embodiment of the disclosure, at least a portion of the second protective member 420 may cover a bending portion 303 connecting the flexible display 299, 300 and a display driver circuit.

In the electronic device 101, 200 according to an example embodiment of the disclosure, the first protective member 410 may include a 1-1th protective member 413 positioned corresponding to the folding region of the flexible display 299, 300. The 1-1th protective member 413 may have a decreased thickness in correspondence to being adjacent to the folding axis A.

In the electronic device 101, 200 according to an example embodiment of the disclosure, the 1-1th protective member 413 may have a decreased thickness such that a lower surface 418 of the 1-1th protective member 413 approaches an upper surface 416 of the 1-1th protective member 413 as the lower surface 418 of the 1-1th protective member 413 becomes adjacent to the folding axis A.

In the electronic device 101, 200 according to an example embodiment of the disclosure, the first housing 213 and the second housing 223 may include a groove 350a having at least a portion of an inner side wall recessed.

In the electronic device 101, 200 according to an example embodiment of the disclosure, a thickness t of the first protective member 410 may be substantially the same as a thickness h of the flexible display 299, 300.

In the electronic device 101, 200 according to an example embodiment of the disclosure, a thickness t of the first protective member 410 may be relatively less than a thickness h of the flexible display 299, 300.

In the electronic device 101, 200 according to an example embodiment of the disclosure, the flexible display 299, 300 may include a display panel 330 and a window cover 320 laminated on an upper surface of the display panel 330. An upper surface 415 of the first protective member 410 may be lower than a film layer located at a topmost layer of the window cover 320.

In the electronic device 101, 200 according to an example embodiment of the disclosure, the window cover 320 may include an adhesive member including an adhesive and located between a glass layer and the film layer. The upper surface 415 of the first protective member 410 may be higher than the adhesive member.

In the electronic device 101, 200 according to an example embodiment of the disclosure, the upper surface 415 of the first protective member 410 may be flat.

In the electronic device 101, 200 according to an example embodiment of the disclosure, the upper surface 415 of the first protective member 410 may be curved toward a rear surface direction.

The electronic device 101, 200 according to an example embodiment of the disclosure may include a plurality of holes 370, 380 formed on a rear surface of the first housing 213 and the second housing 223.

In the electronic device 101, 200 according to an example embodiment of the disclosure, the plurality of holes 370, 380 may include a first hole 370 configured to receive an injected polymer material of the first protective member 410 is injected and a second hole 380 configured to cure the polymer material.

In the electronic device 101, 200 according to an example embodiment of the disclosure, the first hole 370 and the second hole 380 may be different from each other.

An electronic device 101, 200 according to an example embodiment of the disclosure may include a first housing 213, a second housing 223, a hinge assembly 240 including a hinge disposed between the first housing 213 and the second housing 223 and rotatably coupling the first housing 213 and the second housing 223, a flexible display 299, 300 including a first region corresponding to the first housing 213, a second region corresponding to the second housing 223, and a folding region corresponding to the hinge assembly 240 and connecting the first region and the second region, and a protective member 410, 420 comprising a polymer disposed on at least a portion of a periphery of the flexible display 299, 300. The protective member 410, 420 may include a first protective member 410 comprising a polymer material disposed between an edge of the flexible display 299, 300 and a side wall of the first housing 213, and/or disposed between an edge of the flexible display 299, 300 and a side wall of the second housing, and the polymer material may have a specified transparency, a specified permittivity, and a specified dielectric loss.

In the electronic device 101, 200 according to an example embodiment of the disclosure, the polymer material may have an optical density of 1 or more.

In the electronic device 101, 200 according to an example embodiment of the disclosure, the polymer material may have a permittivity of 3.5 or less and a dielectric loss value of 0.02 or less.

In the electronic device 101, 200 according to an example embodiment of the disclosure, the first protective member 410 may be formed by curing a polymer material in a solution state injected through a first hole 370 formed in the first housing 213 or the second housing 223.

In the electronic device 101, 200 according to an example embodiment of the disclosure, the polymer material in a solution state may be cured by ultraviolet light.

In the electronic device 101, 200 according to an example embodiment of the disclosure, the protective member 410, 420 may include a second protective member 420 at least partially disposed between a rear surface of the flexible display 299, 300 and an inner wall of the first housing 213, or at least partially disposed between a rear surface of the flexible display 299, 300 and an inner wall of the second housing 223.

In the electronic device 101, 200 according to an example embodiment of the disclosure, at least a portion of the second protective member may be disposed on an outer periphery of the rear surface.

The electronic device according to embodiments of the disclosure may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1^{st}” and “2^{nd}”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. An electronic device comprising:
a first housing;
a second housing;
a hinge assembly including a hinge disposed between the first housing and the second housing and rotatably coupling the first housing and the second housing;
a flexible display including a first region corresponding to the first housing, a second region corresponding to the second housing, and a folding region corresponding to the hinge assembly and connecting the first region and the second region; and
a protective member disposed on at least a portion of a periphery of the flexible display,
wherein the protective member includes:
a first protective member comprising a polymer disposed between an edge of the flexible display and a side wall of the first housing, and/or disposed between an edge of the flexible display and a side wall of the second housing; and
a second protective member comprising an adhesive at least partially disposed between a rear surface of the flexible display and an inner wall of the first housing, and/or at least partially disposed between a rear surface of the flexible display (299, 300) and an inner wall of the second housing.

2. The electronic device of claim 1, wherein at least a portion of the second protective member is disposed on an outer periphery of the rear surface.

3. The electronic device (101, 200) of claim 1, wherein at least a portion of the second protective member covers a bending portion connecting the flexible display and a display driver circuit.

4. The electronic device of claim 1, wherein the first protective member includes a first first protective member positioned corresponding to the folding region of the flexible display, and
wherein the first first protective member has a thickness decreasing in correspondence to being adjacent to a folding axis.

5. The electronic device of claim 4, wherein the first first protective member has a thickness decreasing such that a lower surface of the first first protective member approaches an upper surface of the first first protective member as the lower surface of the first first protective member becomes adjacent to the folding axis.

6. The electronic device of claim 1, wherein the first housing and the second housing include a groove having at least a portion of an inner side wall recessed.

7. The electronic device of claim 1, wherein a thickness of the first protective member is substantially the same as a thickness of the flexible display.

8. The electronic device of claim 1, wherein a thickness of the first protective member is relatively less than a thickness of the flexible display.

9. The electronic device of claim 1, wherein the flexible display includes a display panel and a window cover laminated on an upper surface of the display panel, and
wherein an upper surface of the first protective member is lower than a film layer located at a topmost layer of the window cover.

10. The electronic device of claim 9, wherein the window cover includes an adhesive member including an adhesive and located between a glass layer and the film layer, and
wherein the upper surface of the first protective member is higher than the adhesive member.

11. The electronic device of claim 9, wherein the upper surface of the first protective member is flat.

12. The electronic device of claim 9, wherein the upper surface of the first protective member is curved toward a rear surface direction.

13. The electronic device of claim 1, comprising a plurality of holes formed on a rear surface of the first housing and the second housing, wherein the plurality of holes include:
a first hole configured to receive an injected polymer material of the first protective member ; and
a second hole configured to cure the polymer material.

14. The electronic device of claim 13, wherein the first hole and the second hole are different from each other.

15. An electronic device comprising:
a first housing;
a second housing;
a hinge assembly including a hinge disposed between the first housing and the second housing and rotatably coupling the first housing and the second housing;
a flexible display including a first region corresponding to the first housing, a second region corresponding to the second housing, and a folding region corresponding to the hinge assembly and connecting the first region and the second region; and
a protective member comprising a polymer disposed on at least a portion of a periphery of the flexible display,
wherein the protective member includes a first protective member comprising a polymer material disposed between an edge of the flexible display and a side wall of the first housing, and/or disposed between an edge of the flexible display and a side wall of the second housing, and wherein the polymer material has a specified transparency, a specified permittivity, and a specified dielectric loss.
